(19) United States
(12) Patent Application Publication
(10) Pub. No.: US 2012/0120568 A1
(43) Pub. Date: May 17, 2012

(54) ELECTRONIC DEVICE WITH CONNECTION STRUCTURE

(75) Inventor: FANG-KENG HSIEH, Tu-Cheng (TW)

(73) Assignee: HON HAI PRECISION INDUSTRY CO., LTD., Tu-Cheng (TW)

(21) Appl. No.: 13/095,886

(22) Filed: Apr. 28, 2011

(30) Foreign Application Priority Data
Nov. 15, 2010 (CN) 201010544029.8

(51) Int. Cl. H05K 7/00

(52) U.S. Cl. 361/679.01

(57) ABSTRACT

An electronic device includes a front cover and a back cover. A number of first connecting members are fixed to the back cover, and each of the plurality of first connecting members is made of elastically deformable material and defines a first hole. A number of second connecting members are fixed to the front cover, and each of the plurality of second connecting members includes a protruding post. The protruding post engages the first hole to connect the front cover to the back cover.

### BACKGROUND

1. Technical Field

The present disclosure relates to electronic devices, and particularly, to an electronic device having a new connection structure.

2. Description of Related Arts

Electronic devices such as digital photo frames typically include a front cover and a back cover. Conventionally, the front cover and the back cover can be connected together with fasteners, such as screws, or other conventional connection techniques. In spite of this, it is still desirable for a new connection structure for connecting the front cover and the back cover.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric, exploded view of an electronic device in accordance with an embodiment.

FIG. 2 is an isometric view of a front cover of the electronic device of FIG. 1, viewed from a different perspective.

FIG. 3 is a partial, planar cross-sectional view showing the internal structure of the electronic device.

### DETAILED DESCRIPTION

Embodiments of the present disclosure will now be described in detail below, with reference to the accompanying drawings.

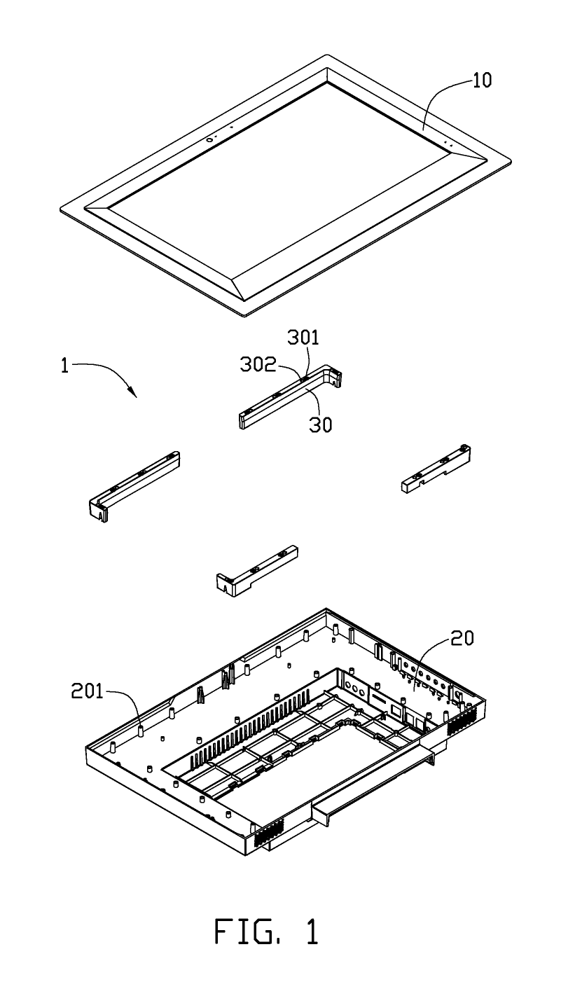

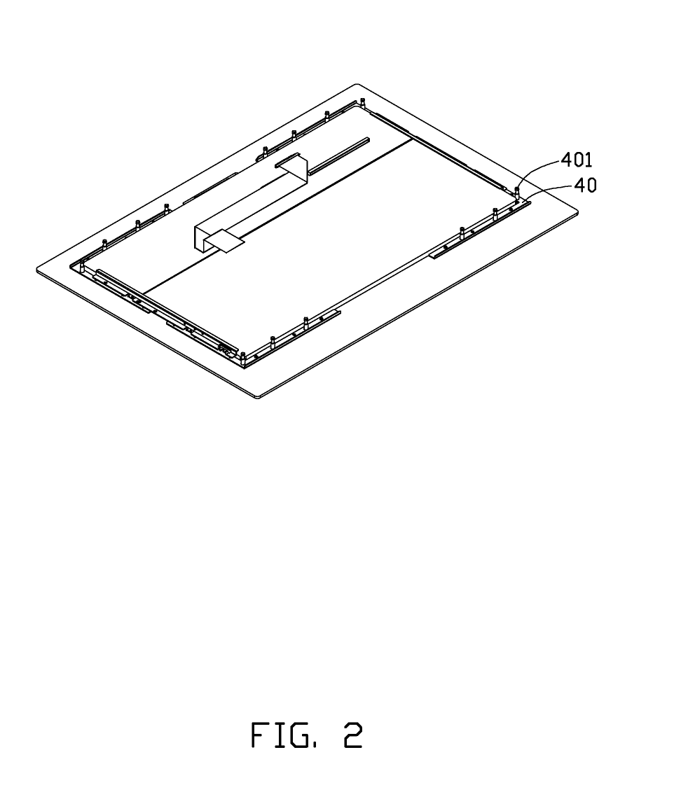

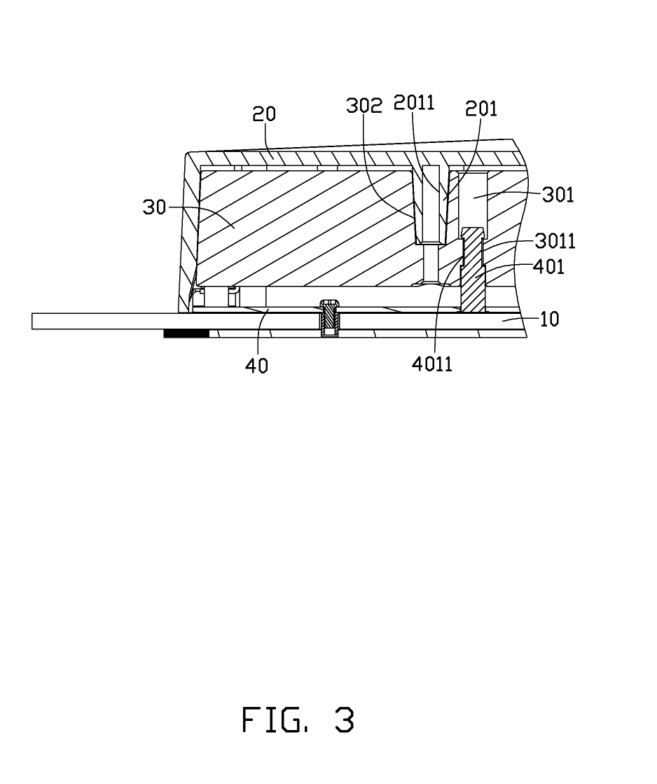

Referring to FIGS. 1 and 2, an electronic device 1 includes a front cover 10, a back cover 20, a number of first connecting members 30, and a number of second connecting members 40. The font cover 10 and the back cover 20 are connected together by the engagement between the connecting members 30 and the connecting members 40. In the embodiment, the electronic device 1 is a digital photo frame, with a display and other required components omitted. The back cover 20 includes a number of protruding posts 201. In the embodiment, each protruding post 201 defines a threaded hole 2011 (FIG. 3).

Referring to FIG. 3, each connecting member 30 is L shaped and defines a number of first holes 301 and a number of second holes 302, both extending along a widthwise direction. Each connecting member 30 is made of elastically deformable rubber. An annular protrusion 3011 protrudes from the inner lateral surface of each hole 301.

Each connecting member 40 is an L-shaped tab and includes a number of protruding posts 401. Each protruding post 401 defines an annular groove 4011 extending around the lateral surface thereof.

During assembly, the connecting members 40 are respectively fixed to the inner side of the front cover 10 by conventional connection techniques, such as screws. The connecting members 30 are then fixed to the back cover 20 with screws (not shown) inserted into the second holes 302 and screwed into the threaded holes 2011 of the protruding post 201 received in the second holes 302. The front cover 10 is then orientated to align the protruding posts 401 of the connecting members 40 with the first holes 301 of the connecting members 30, and then moved to cause the protruding posts 401 to be inserted into the corresponding first holes 301. After the protruding posts 401 are totally inserted into the first holes 301, the annular protrusion 3011 engages the annular groove 4011, which prevents the protruding posts 401 from disengaging from the first holes 301, thereby connecting the front cover 10 to the back cover 20.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. An electronic device comprising:
a front cover;
a back cover;
a plurality of first connecting members fixed to the back cover, and each of the plurality of first connecting members being made of elastically deformable material and defining a first hole;
a plurality of second connecting members fixed to the front cover, and each of the plurality of second connecting members comprising a protruding post, wherein the protruding post engages the first hole to connect the front cover to the back cover.

2. The electronic device according claim 1, wherein each of the plurality of first connecting members is made of soft rubber.

3. The electronic device according claim 1, wherein the plurality of first connecting members are fixed to the back cover by screws.

4. The electronic device according claim 1, wherein the plurality of second connecting members are fixed to the front cover by screws.

5. The electronic device according claim 1, wherein an annular protrusion protrudes from an inner lateral surface of the first hole, an annular groove extends around a lateral surface of the protruding post, the annular protrusion engages the annular groove to connect the front cover to the back cover.

6. The electronic device according claim 1, wherein each of the plurality of second connecting members is L-shaped.
